(19) United States
(12) Patent Application Publication
(10) Pub. No.: US 2024/0413011 A1
(43) Pub. Date: Dec. 12, 2024

(54) AUTOMATED DIAL-IN OF ELECTROPLATING PROCESS PARAMETERS BASED ON WAFER RESULTS FROM EX-SITU METROLOGY

(71) Applicant: Applied Materials, Inc., Santa Clara, CA (US)

(72) Inventors: Jing Xu, Kalispell, MT (US); John L. Klocke, Kalispell, MT (US); Paul R. McHugh, Kalispell, MT (US); Marvin L. Bernt, Kalispell, MT (US)

(73) Assignee: Applied Materials, Inc., Santa Clara, CA (US)

(21) Appl. No.: 18/332,964

(22) Filed: Jun. 12, 2023

(51) Int. Cl. H01L 21/768; H01L 21/288; H01L 21/66

(52) U.S. Cl. CPC H01L 21/76873; H01L 21/288; H01L 21/76877; H01L 22/12

(57) ABSTRACT

A method of plating substrates may include receiving characteristics of a plating chamber and characteristics of a substrate to be placed in the plating chamber to be provided as inputs to a trained model. An inference operation using the trained model may be performed to generate a recipe for the plating chamber. The recipe may include characteristics of a forward plating current and characteristics of a reverse de-plating current that may be applied in order to add and remove metal to maintain co-planarity and pillar quality. The plating operation may be performed on the substrate using the recipe that was output from the trained model to cause a current to be applied to the plating liquid in the plating chamber to deposit a metal on exposed portions of the substrate, wherein the current comprises alternating cycles of the forward plating current; and the reverse de-plating current.

### TECHNICAL FIELD

The field of the invention is electroplating semiconductor material substrates or wafers, and similar types of substrates.

### BACKGROUND

Metallization of electrical connections has been widely used in many semiconductor applications, ranging from dual damascene to various packaging structures, including C4 bumping, pillars, micro-bumps, redistribution layers (RDL), thru-silicon vias (TSV), etc. Such metallization is commonly carried out using techniques such as electro-deposition of different metals, such as copper, gold, nickel, solder, and others. As technology advances, the chip layout increasingly has features and pattern densities that are difficult to plate or metallize uniformly.

Electro-deposition of advanced microelectronic device packaging often uses a mask or a photoresist layer to define the pattern of metal lines or contacts. The pattern can also be defined by non-reacting or non-conducting surfaces. As used here, the term patterned substrate means a substrate having a mask or photoresist layer or non-reacting or non-conducting regions. The pattern density may vary between sparsely patterned regions and densely patterned regions. This causes corresponding variations in local current density and ion concentration differences, which affect deposition thickness uniformity within a die (the so-called within die nonuniformity, or WID non-uniformity). Therefore, improved plating techniques are needed.

### SUMMARY

In some embodiments, a method of plating semiconductor substrates may include receiving one or more characteristics of a plating chamber comprising a plating liquid and configured to perform plating operations on semiconductor substrates; receiving one or more characteristics of a substrate to be placed in the plating chamber; and providing inputs to a trained model. The inputs may include the one or more characteristics of the plating chamber and the one or more characteristics of the substrate. The method may also include performing an inference operation using the trained model to generate an output comprising at least a portion of a recipe for the plating chamber. The portion of the recipe may include characteristics of a forward plating current and characteristics of a reverse de-plating current. The method may further include causing a plating operation to be performed on the substrate using at least the portion of the recipe that was output from the trained model. The recipe may cause a current to be applied to the plating liquid in the plating chamber to deposit a metal on exposed portions of the substrate. The current comprises alternating cycles of the forward plating current and the reverse de-plating current.)

In some embodiments, a controller for a plating chamber may include one or more processors and one or more memory devices storing instructions that, when executed by the one or more processors, cause the one or more processors to perform operations including receiving one or more characteristics of a plating chamber comprising a plating liquid and configured to perform plating operations on semiconductor substrates; receiving one or more characteristics of a substrate to be placed in the plating chamber; and providing inputs to a trained model. The inputs may include the one or more characteristics of the plating chamber and the one or more characteristics of the substrate. The operations may also include performing an inference operation using the trained model to generate an output comprising at least a portion of a recipe for the plating chamber. The portion of the recipe may include characteristics of a forward plating current and characteristics of a reverse de-plating current. The operations may further include causing a plating operation to be performed on the substrate using at least the portion of the recipe that was output from the trained model. The recipe may cause a current to be applied to the plating liquid in the plating chamber to deposit a metal on exposed portions of the substrate. The current comprises alternating cycles of the forward plating current and the reverse de-plating current.

In some embodiments, a non-transitory computer-readable medium may include instructions that, when executed by one or more processors, cause the one or more processors to perform operations including receiving one or more characteristics of a plating chamber comprising a plating liquid and configured to perform plating operations on semiconductor substrates; receiving one or more characteristics of a substrate to be placed in the plating chamber; and providing inputs to a trained model. The inputs may include the one or more characteristics of the plating chamber and the one or more characteristics of the substrate. The operations may also include performing an inference operation using the trained model to generate an output comprising at least a portion of a recipe for the plating chamber. The portion of the recipe may include characteristics of a forward plating current and characteristics of a reverse de-plating current. The operations may further include causing a plating operation to be performed on the substrate using at least the portion of the recipe that was output from the trained model. The recipe may cause a current to be applied to the plating liquid in the plating chamber to deposit a metal on exposed portions of the substrate. The current comprises alternating cycles of the forward plating current and the reverse de-plating current.

In any embodiments, any and all of the following features may be implemented in any combination and without limitation. The method/operations may also include causing the substrate to be transferred from the plating chamber to a metrology station, and causing metrology station to analyze the substrate and obtain metrology data for the substrate. The metrology data may include a measure of a within-wafer or within-die co-planarity of metal pillars that fill the exposed portions of the substrate during the plating operation. The metrology data may include a characterization of a quality of metal pillars that fill the exposed portions of the substrate during the plating operation. The method/operations may also include receiving measured metrology data for the substrate; determining that the measured metrology data matches a target metrology data for the substrate; and in response to determining that the measured metrology data matches the target metrology data, causing the plating operation to be performed on a plurality of additional substrates of a same type as the substrate using the recipe that was output from the trained model. The method/operations may also include determining that the measured metrology data does not match a target metrology data for the substrate; and in response to determining that the measured metrology data matches the target metrology data, performing a retraining operation on the trained model using the recipe, the measured metrology data, the one or more characteristics of the plating chamber, and the one or more characteristics of the substrate. The retraining operation may include adjusting internal weights or parameters of the trained model using the one or more characteristics of the plating chamber, the one or more characteristics of the substrate, and the measured metrology data as inputs, and using the recipe as a labeled output. The method/operations may also include repeatedly performing iterative operations until the measured metrology data matches the target metrology data, where the iterative operations include providing the inputs to the trained model after the retraining operation has been performed; generating a next recipe using the trained model; causing the plating operation to be performed on a next substrate using the next recipe; receiving next measured metrology data for the next substrate after the plating operation is performed; and determining whether the next measured metrology data matches the target metrology data. The inputs to the trained model may further include target metrology data. The one or more characteristics of the substrate may be received as a GDS file for the substrate. The one or more characteristics of the substrate may include a characterization of an amount of masked area of the substrate relative to the exposed portions of the substrate. The one or more characteristics of the substrate may include a diameter or pitch of vias that form the exposed portions of the substrate. The one or more characteristics of the plating chamber may include a temperature or pressure of the plating chamber. The substrate may include a photoresist or mask layer that defines a pattern on the substrate, and the pattern may include exposed portions of the substrate adjacent to an open area, where a current density during a plating process may be more concentrated at the exposed portions of the substrate adjacent to the open area compared to exposed portions of the substrate that are not adjacent to the open area. During the forward plating current, the metal may be deposited unevenly on the exposed portions of the substrate. During the reverse deplating current, the metal may be removed such that the metal becomes evenly distributed on the exposed portions of the substrate. The forward plating current and the reverse deplating current may both be applied in alternating cycles in the plating chamber when the substrate is in the plating liquid without using separate chambers or plating liquids to apply the forward plating current and the reverse deplating current. The exposed portions of the substrate may include a plurality of thru-silicon vias (TSVs), where a difference between a maximum height of the TSVs and a minimum height of the TSVs may be greater than a threshold distance.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIGS. 1-2 illustrate an electrochemical processor, according to some embodiments.

FIG. 3 illustrates a substrate that may be subject to nonuniform plating, according to some embodiments.

FIG. 4 illustrates a process for plating and deplating material from features to achieve a uniformly co-planar design, according to some embodiments.

FIG. 5 illustrates a diagram of a training process for training a machine-learning model, according to some embodiments.

FIGS. 6-8 illustrate graphs of the resulting co-planarity using different current characteristics, according to some embodiments.

FIG. 9 illustrates a flowchart of a method for plating semiconductor substrates, according to some embodiments.

FIG. 10 illustrates a block diagram that illustrates the inference steps performed by the method of flowchart, according to some embodiments.

FIG. 11 illustrates a flowchart of a method for refining the trained model for a specific substrate type, according to some embodiments.

FIG. 12 illustrates a block diagram of the operations performed by the method of flowchart, according to some embodiments.

FIG. 13 illustrates an exemplary computer system, in which various embodiments may be implemented.

### DETAILED DESCRIPTION

The embodiments described herein provide an improved method for plating a substrate with material while maximizing within-die uniformity and co-planarity. Each patterned substrate will react differently in a plating chamber, having unique patterns, masks, and amounts/locations of open areas on the die. These open areas that are covered with a mask or photoresist layer may cause current to pool on adjacent exposed areas during the plating process, causing more material to be deposited on those adjacent exposed areas. Traditionally, the substrate was then transferred from the plating chamber to a separate deplating chamber into a electrochemical bath having a lower conductivity. A reverse current was then applied to remove the excess material on the substrate such that vias and traces ended up at a uniform height.

These embodiments improve the batch processing of patterned substrates and improve the uniformity of the plating process by utilizing a machine-learning approach that trains a model to automatically dial-in the process parameters for a plating operation based on ex-situ metrology results. A universal model may first be trained using metrology data that characterizes the pillar quality and/or co-planarity of a large number of plated substrates that have previously undergone the plating process. The training process may incorporate the recipe used by the previous processes, along with characteristics of the chamber and/or the previous substrates. The trained model may then be used to generate an initial recipe for a new substrate type to undergo the plating process. The universal trained model may be used with the chamber characteristics and substrate characteristics for this new substrate. After the plating process, the measured metrology data for the new substrate may be compared to the target metrology data used to generate the initial recipe. If the measured metrology data is acceptable, the recipe may be used to plate a batch of similar substrate types. However, if the measured data does not match, an iterative retraining process may be performed to customize the universal model for this particular substrate type, thereby quickly generating a substrate-specific model from the universal model. A small number of additional substrates may be plated, and the model may be iteratively retrained after each plating process. The universal model may then be quickly dialed-in for the specific wafer type to identify the optimal recipe. This greatly reduces the number of trial substrates that are needed to identify the operating characteristics in the recipe, particularly for the forward plating and reverse de-plating current. This in turn improves substrate throughput and reduces wasted substrates.

By way of example, a plating chamber that uses electrochemical deposition (ECD) processes is described below. However, other plating processes in addition to ECD may be used with the forward/reverse current techniques described herein. Therefore, this specific ECD chamber and ECD processes in general are not meant to be limiting.

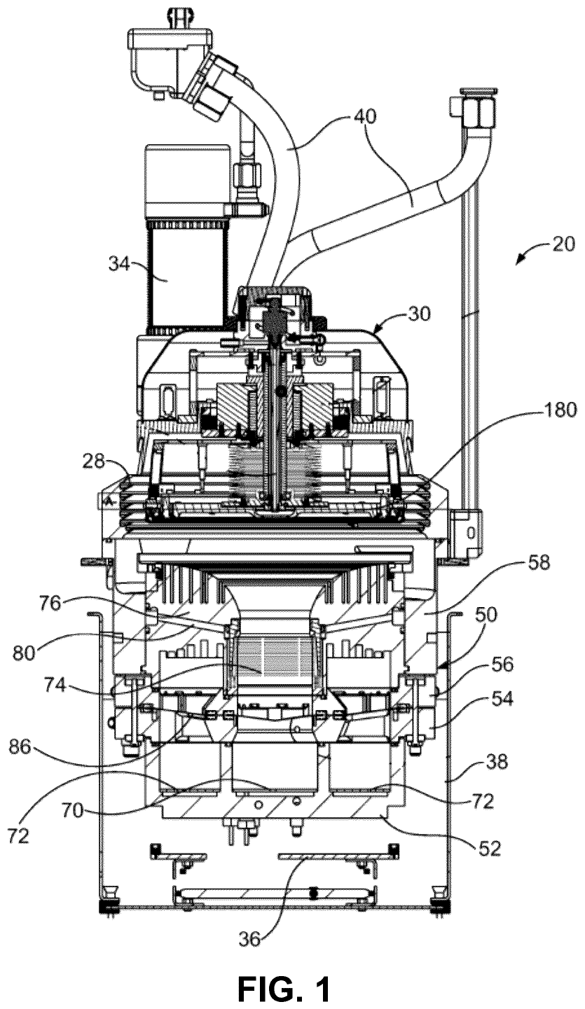

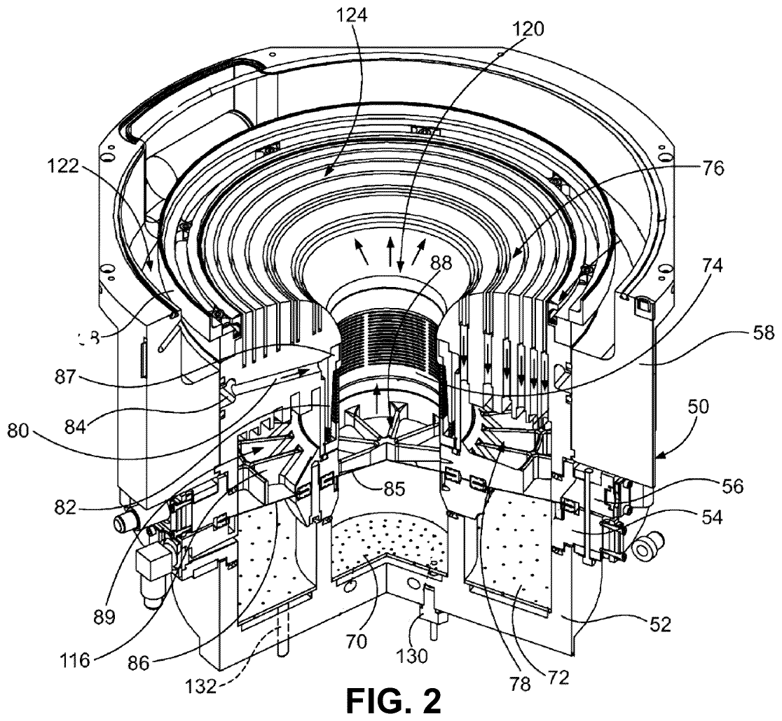

FIGS. 1-2 illustrate an electrochemical processor 20, according to some embodiments. The electrochemical processor 20 may include a head positioned above a vessel assembly 50. The vessel assembly 50 may be supported on deck plate 24 and a relief plate 26 attached to a stand 38 or other structure. A single processor 20 may be used as a standalone unit. Alternatively, multiple processors 20 may be provided in arrays with workpieces loaded and unloaded in and out of the processors by one or more robots. A head 30 may be supported on a lift/rotate unit 34, for lifting and inverting the head to load and unload a workpiece into the head, and for lowering the head 30 into engagement with the vessel assembly 50 for processing.

Electrical control and power cables 40 may be linked to the lift/rotate unit 34 and to internal head components and may lead up from the processor 20 to facility connections, or to connections within multi-processor automated system. A rinse assembly 28 having tiered drain rings may be provided above the vessel assembly 50. A drain pipe 42 may connect the rinse assembly 28, if used, to a facility drain. An optional lifter 36 may be provided underneath the vessel assembly 50 to support the anode cup during changeover of the anodes. Alternatively, the lifter 36 may be used to hold the anode cup up against the rest of the vessel assembly 50.

The vessel assembly 50 may include an anode cup 52, a lower membrane support 54, and upper membrane support 56 held together with fasteners 60. Within the anode cup 52, a first or inner anode 70 may be positioned near the bottom of an inner anolyte chamber 110. A second or outer anode 72 may be positioned near the bottom of an outer anolyte chamber 112 surrounding the inner anolyte chamber 110. The inner anode 70 may be a flat round metal plate, and the outer anode 72 may be flat ring-shaped metal plate, for example, a platinum plated titanium plate. The inner and outer anolyte chambers may be filled with copper pellets. The inner anode 70 may be electrically connected to a first electrical lead or connector 130, and the outer anode 72 may be electrically connected to a separate second electrical lead or connector 132. In some embodiments, for example for processing 300 mm diameter wafers, the processor may have a center anode, and a single outer anode. Designs having three or more anodes may also optionally be used, especially with even larger wafers.

An upper cup 76 may be contained within or surrounded by an upper cup housing 58. The upper cup housing 58 may be attached to and sealed against the upper cup 76. The upper cup 76 may have a curved upper surface 124 and a central through opening that forms a central or inner catholyte chamber 120. This chamber 120 is defined by the generally cylindrical space within a diffuser 74 leading into the bell or horn shaped space defined by the curved upper surface 124 of the upper cup 76. A series of concentric annular slots extend downwardly from the curved upper surface 124 of the upper cup 76. An outer catholyte chamber 78 formed by the bottom of the upper cup 76 is connected to the rings via an array of tubes or other passageways.

Similarly, a second or outer membrane 86 may be secured between the upper and lower membrane supports and may separate the outer anolyte chamber 112 from the outer catholyte chamber 78. An outer membrane support 89, which may be provided in the form of radial legs 116 on the upper membrane support 56, supports the outer membrane from above.

A diffuser circumferential horizontal supply duct 84 may be formed in an outer cylindrical wall of the upper cup 76, with the duct 84 sealed by O-rings or similar elements between the outer wall of the upper cup 76 and the inner cylindrical wall of the upper cup housing 58. Radial supply ducts 80 may extend radially inwardly from the circumferential duct 84 to an annular shroud plenum 87 surrounding the upper end of the diffuser shroud 82. The radial ducts 80 pass through the upper cup 76 in between the vertical tubes connecting the annular slots in the curved upper surface 124 of the upper cup 76 to the outer catholyte chamber 78. The circumferential duct 84 and the radial ducts 80 lead to the shroud plenum 87, and the outer catholyte paths may be formed between the diffuser shroud 82 and the diffuser 74. These outer catholyte paths may ordinarily be filled with liquid catholyte during operation of the processor 20.

In use, a workpiece, typically having an electrically conductive seed layer, is loaded into the head. In some embodiments, the workpiece may be first loaded into a wafer carrier or a wafer holder, and the wafer carrier/folder may then be transferred into the chamber. The seed layer on the workpiece is connected to an electrical supply source, typically to the cathode. If the head is loaded in a face up position, the head is flipped over so that the rotor, and the workpiece held in the rotor, are facing down. The head is then lowered onto the vessel until the workpiece is in contact with the catholyte in the vessel. The spacing between the work piece and the curved upper surface of the upper cup influences the current density uniformity at the workpiece Surface. This gap may be changed during processing. The workpiece may be moved up and away from the surface gradually, or it may be moved quickly from a starting gap to an ending gap. A lift/rotate mechanism may be used to lift the head.

Anolyte is provided into the inner anolyte chamber and separately into the outer anolyte chamber. Catholyte is provided into the circumferential supply duct. Catholyte is supplied to the inlet fitting. The workpiece is moved into contact with the catholyte, typically by lowering the head. Electrical current to the anodes 70 and 72 is switched on with current flowing from the anodes through the anolyte in the inner and outer anolyte chambers. The electrical current from the inner and outer anodes passes through the anolyte and through the inner and outer membranes and into the catholyte contained in the open spaces in the upper cup 76.

Within the upper cup 76, catholyte flows from the supply duct 84 radially inwardly to the diffuser shroud plenum 87 and then into the diffuser 74. The catholyte flows up from the diffuser and moves radially outwardly in all directions over the curved upper surface 124 of the upper cup 76. Metal ions in the catholyte deposit onto the workpiece, building up a metal layer on the workpiece. The motor may be switched on to rotate the rotor and the workpiece, to provide more uniform deposition onto the workpiece. Most of the catholyte then flows into the collection ring 122. A small fraction of the catholyte flows downwardly through the slots and the tubes into the outer catholyte chamber 78. The catholyte then flows out of the processor 20.

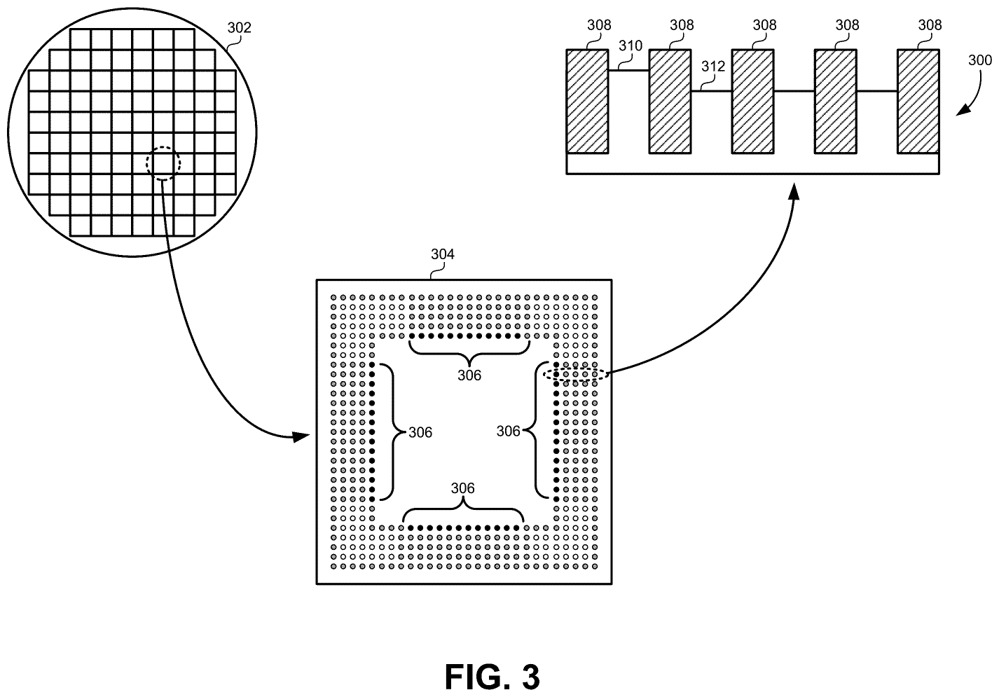

FIG. 3 illustrates a substrate 302 that may be subject to nonuniform plating, according to some embodiments. A substrate 302 may include any type of material, such as a silicon semiconductor substrate upon which integrated circuits and other electrical components may be fabricated. The substrate 302 may include multiple individual dies 304. When processing is complete, the substrate 302 may be separated into the individual dies 304 and packaged individually. When considering the uniformity of layers of material that are formed on the substrate 302, some processes may focus on uniformity within a single die 304. Other processes may focus more on uniformity within a coupon, or subset of dies on the substrate 302. Other processes may additionally or alternatively focus on uniformity across the substrate 302 as a whole.

The terms “wafer,” “workpiece,” and “substrate” may be used here interchangeably. The substrate may have various shapes, sizes, and materials. The present methods may be used in plating copper, as well as other metals such as silver, gold, nickel, cobalt, palladium, tin, etc. A patterned substrate may refer to a substrate that has a photoresist or mask layer that defines a pattern. Alternatively, a patterned substrate may refer to a substrate that contains structures already patterned, such as a redistribution layer (RDL) after photoresist removal, or through-silicon via (TSV) layer after electroplating. Although patterning on a substrate is often the source of plated film non-uniformity, the present methods may be used to provide a more uniform plated film, regardless of the source of the non-uniformity in the initial plated film.

During a plating process, the substrate 302 may be immersed in a liquid electrolyte, and a forward current may be applied to anodes in the chamber to deposit a layer of metal on the substrate 302. For example, each die 304 may include a mask or photoresist layer that covers the die 304. Areas on the mask may leave portions of the substrate exposed to the plating process. In this example, the mask on the die 304 may leave a series of circular openings on the surface of the die 304 where metal vias may be deposited. Any voids in the mask that leave the substrate exposed to the plating process may be referred to as “exposed” areas of the substrate.

An object of most plating processes is to uniformly deposit material on the exposed areas of the substrate 302. However, each new design for a substrate pattern may have its own unique layout of open areas, feature densities, and circuit patterns as defined by the mask during the plating process. Because these patterns will be different for every design, currents may be pooled differently during the plating process. For example, the die 304 includes a large open area in the center of the die 304. As used herein, the term “open” areas may refer to areas that do not include features or voids in the mask that leave the substrate exposed. For example, a large open area on the die 304 would include the center section of the die 304 where the density of the exposed areas is significantly less than the areas with the vias that surround the open area. The chemistry bath liquid may cover the die uniformly, and the current may flow through the chemistry in a relatively uniform manner. However, open areas may cause the current flux from those open areas to be funneled into the adjacent vias during electroplating. It is also harder for current be delivered uniformly into relatively dense via areas. For example, current may tend to pool or concentrate in the open area at the center of the die 304 and thus be funneled more heavily into features that are defined by the exposed portions of the substrate 302 that are adjacent to the open area. This may include the vias 306 that are adjacent to the open area. When more current is funneled into these vias that are adjacent to the open area, more material will be deposited in these vias during the plating process.

A cross-sectional view 300 of the die 304 illustrates how an exposed area 310 of the die 304 that is adjacent to the open area in the center of the die 304 may result in more material being plated in the exposed area 310. The photoresist mask 308 may leave the vias open (e.g., 200 microns deep), then fill the vias with metal during the plating process. This results in a via having a taller height than other exposed areas 312 that are not adjacent to the open areas, even though the mask 308 may have the same uniform height. Co-planarity may be defined as the difference between a maximum height of a via (or other feature) and a minimum height of a via (or other feature). Co-planarity is typically measured as the max-min on the same die 304, but may also be measured on a coupon of dies and/or the substrate 302 as a whole.

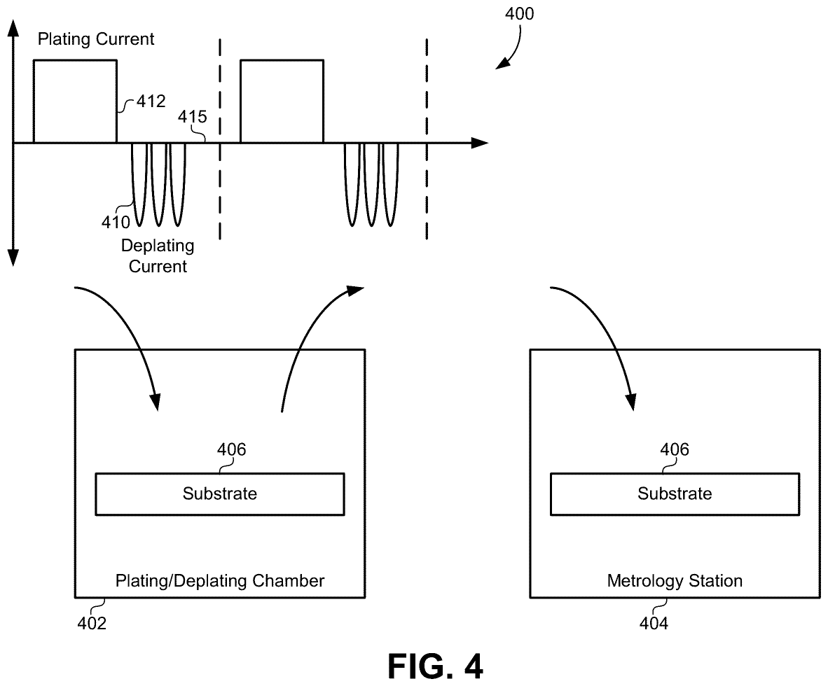

FIG. 4 illustrates a process for plating and deplating material from features to achieve a uniformly co-planar design, according to some embodiments. First, the substrate 406 may be placed within a plating chamber 402. The plating chamber 402 may include a liquid chemistry having a relatively high conductivity. A forward current may then be applied through the liquid to perform the plating process. A forward current may be defined as a current configured to cause material to form on the substrate. As described above, this forward current process in the plating chamber 402 may result in features that are not co-planar across a die or the substrate as a whole. The substrate may include a silicon wafer plated with an initial patterned copper film, although other types of substrates and metals may be used. The patterning may affect current density during the forward plating so that the initial plated film is non-uniform to a degree. For example, the initial film may be at least 3, 5, 8 or 10% non-uniform (per three sigma/mean). The initial metal film can be formed in various ways, such as electrochemical deposition (plating).

In order to remove excess material, the plating chamber 402 may then apply a reverse current through the liquid to perform the deplating process. A reverse current may be defined as a current configured to cause material to be removed from the substrate. The reverse current may also be referred to as a de-plating current. The reverse current properties may be configured to remove material faster from the vias adjacent to the open space, eventually balancing out the heights of the features across the die. The de-plating current may thus remove excess material in the higher vias that was deposited during the forward plating current cycles in order to make the height of the pillars uniform across the die and/or substrate after each cycle. This allows the process to preferentially remove material from the vias that are taller after each cycle to achieve co-planarity.

The forward plating current and reverse de-plating current may be applied based on at least a portion of a recipe used to execute the plating process. The recipe may include any or all characteristics of the forward and/or reverse currents. For example, the recipe may include a waveform type for a forward current 412 and/or a reverse current 410, such as a square wave, sawtooth wave, sinusoidal wave, and so forth. As illustrated in FIG. 4, either of the waveforms may include multiple pulses (e.g., the reverse current 410) and/or a continuous waveform (e.g., the forward current 412). The recipe may also include a frequency for the alternating cycles of the forward current 412 and the reverse current 410. This may include a duty cycle for each current type, along with any delays or off-times 415 that occur during each cycle. Embodiments may also include magnitudes or current densities of the forward/reverse currents. As described below, these characteristics of the forward current 412 and reverse current 410 waveforms may to a large extent determine the quality and/or co-planarity of the deposited metal pillars on the substrate.

After iterating back and forth between the forward and reverse currents, the plated and de-plated substrate 406 may then be rinsed and dried, and then subjected to additional chemical or electrochemical processing. At some point after the substrate 406 has completed the plating process in the plating chamber 402, the substrate 406 may be placed in a metrology station 404. The metrology station may be configured to perform a full metrology scan on the substrate 406. The metrology station 404 may analyze the substrate and obtain metrology data for the substrate.

The metrology data may include a very large set of characteristics measured from the substrate 406, including film thicknesses, surface defects, and so forth. More specifically, the embodiments described herein may utilize a subset of the metrology data captured by the metrology station 404. This metrology data may include characteristics that specifically relate to the co-planarity and/or quality of the pillars of metal that filled the features or holes in the masked substrate during the plating process. For example, the metrology data may include a measure of the within-wafer and/or the within-die co-planarity of the metal pillars in the exposed portions of the substrate. This may include individual heights of one or more of the pillars, a statistical characterization of the pillar heights, a characterization of the overall co-planarity (e.g., within 5%), and/or any other metric related to the heights of the metal pillars formed during the plating process.

The metrology data may also include a characterization of a quality of the metal pillars. In addition to measuring the heights of the pillars, the metrology data may also detect surface variations or defects in the pillar surfaces. These defects may include deformations, pitting, holes, protrusions, bumps, surface irregularities, narrowing pillars, rounded edges, and/or any other characteristic of the surface or shape of the pillars. For example, different frequencies used to apply the forward plating current and the reverse de-plating current cycles may generate more surface defects in the pillars. The characterization of these defects in the metrology data may include a scalar value (e.g., between 0.0 and 1.0) that characterizes the quality of the surfaces of the pillars. In some embodiments, the metrology data may include images, x-rays, or scans of the pillars, and these images may be characterized by a human user. For example, a user may visually analyze the images of the pillars and label them with enumerated categories of quality (e.g., unacceptable, acceptable, good, very good, etc.) that may then be digitally encoded for the machine-learning training algorithm.

Prior to this disclosure, the process for determining the recipe, including the characteristics of the forward currents and the reverse currents, required a large amount of trial-and-error and resulted in a large number of wasted substrates. To solve this and other technical problems, the embodiments described herein utilize a machine-learning method to both universally and specifically training a model to determine and refine the recipe parameters for plating a substrate. This procedure described below for training and using a machine-learning model dramatically reduces the number of wasted substrates and significantly increases the throughput of wafers that may be processed as a batch using the same recipe. Additionally, the machine-learning model greatly improves the characteristics of the forward plating current and the reverse de-plating current to improve the co-planarity and quality of the metal pillars produced during the plating process. Thus, the use of the machine-learning model as described below improves the technology for uniformly plating features on substrates that may include different designs and/or chamber characteristics.

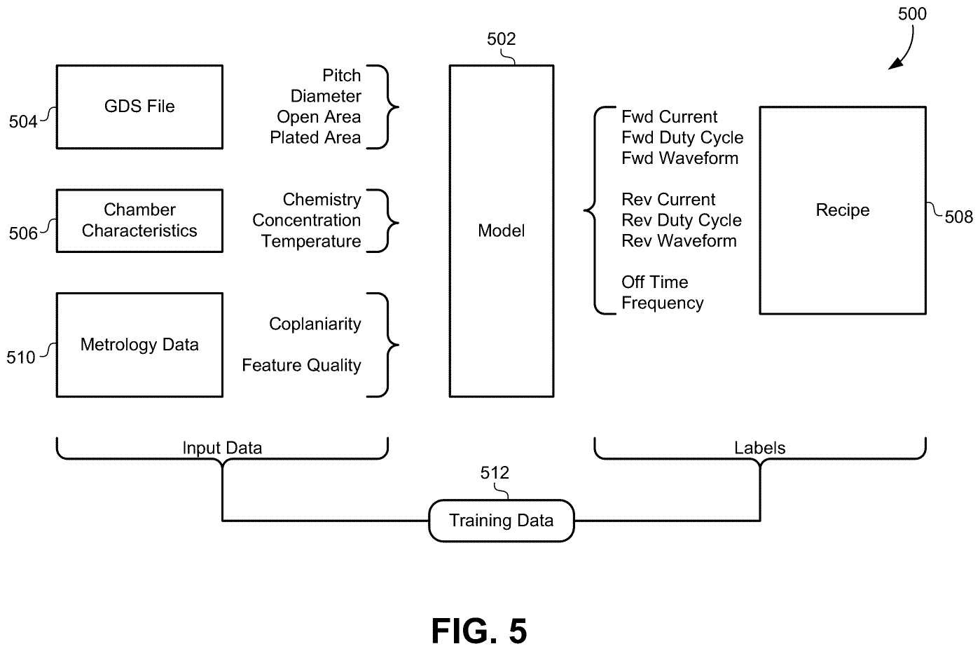

FIG. 5 illustrates a diagram 500 of a training process for training a machine-learning model 502, according to some embodiments. The model 502 may be implemented using any type of classification model, such as a neural network, a logistic regression model, a K-nearest neighbors model, a decision tree, a support vector machine, a Naive Bayes model, a random forest, a gradient boosting model, and/or any other type of model. The model may be trained from existing metrology data and recipes used to perform previous plating processes on existing substrates. For example, as plating processes are performed in each chamber, the metrology data from these substrates, as well as the associated processing conditions, may be recorded and used as training data for the model 502.

In some embodiments, the training data may be selected from plating processes performed on different types of substrates. For example, training data may be received for substrates having different mask patterns that produce different dies and chip designs. Therefore, one of the inputs to the model 502 may include one or more characteristics of the substrate being processed. These characteristics may be received as part of a GDS file, which is a standard file type representing geometric designs on a substrate. These characteristics may include a pitch of the features (e.g., holes in a mask layer in which metal pillars are formed), diameters of the features, open area covered by a mask on the substrate, exposed areas of the substrate where plating occurs, a percentage of the open versus exposed areas, and/or any other characteristic of the substrate. To create a model 502 that is universal, the characteristics of the substrate 504 may be provided as an input. Alternatively, some embodiments may train the model 502 specifically for one type or class of substrates, and the characteristics of the substrate 504 may be omitted.

Training data may also include one or more chamber characteristics 506 received from different plating chambers, which may use processes with different plating characteristics. For example, these different plating characteristics may include different chemistries for the plating liquid, different concentrations of the plating liquid, and/or different environmental conditions such as temperature, pressure, humidity, and so forth. These plating chambers may be chambers of the same type (e.g. chambers from the same manufacturer that process substrates in a facility in parallel). Alternatively, different types of plating chambers may be represented in the training data.

The training process may also provide the metrology data for each of the previously plated substrates as a training input for the model 502. As described above, the metrology data 510 may include any characteristics of the substrate as measured by a metrology station after the plating process is complete. Such metrology data 510 may include a characterization of the co- planarity of the substrate (e.g., within-die or within-substrate co-planarity), heights of the pillars, a characterization of the quality of the pillars, and so forth.

The training data 512 may include any and/or all of the inputs described above. The training data 512 may label these inputs using the recipe 508 used in the plating process for each of the substrates. Thus, the model 502 may be trained to output a recipe that matches the characteristics of the substrate 504, the chamber characteristics 506, and/or the metrology data 510. As described above, the recipe may include any of the operating characteristics of the plating chamber during the plating process. Specifically, some embodiments may include characteristics of the forward current and/or the reverse current for the plating and de-plating iterative cycles. These current characteristics may include current magnitudes, current waveforms, duty cycles, frequencies, off time, and so forth. For example, the model 502 be trained to output numerical values for each of these currents characteristics.

A large number of previous plating processes may form the training data 512. The training process may include setting or adjusting internal weights or parameters of the model 502 such that the inputs provided for each set of training data 512 are more likely to generate the corresponding output recipe 508. This training process may be referred to herein as a universal training process, since the model 502 is trained to output recipes for a larger population of plating chambers and/or substrate designs. Alternatively, the process may be executed in a more-specific manner to target a particular substrate design and/or a specific chamber. This universal training process may be referred to as an initial training process that generates a universal version of the model 502, which may later be used to provide an initial recipe for subsequent substrate designs and/or plating chambers.

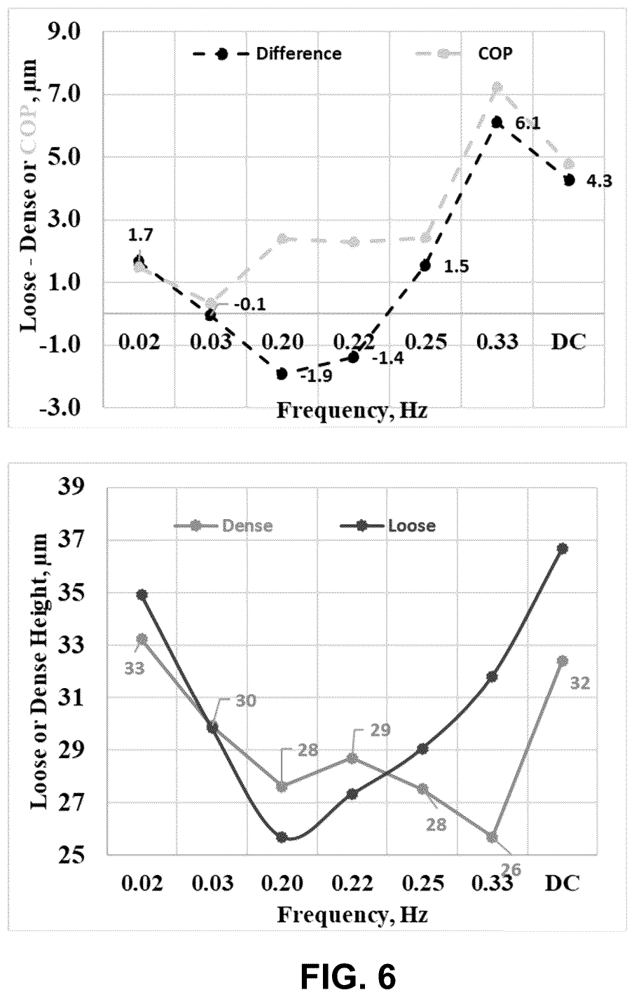

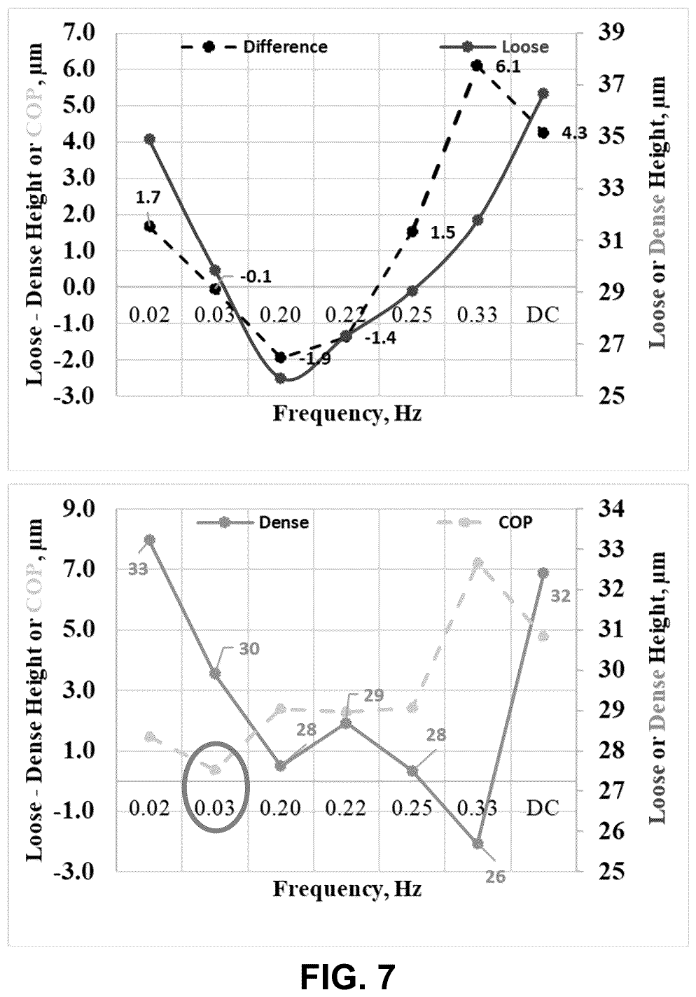

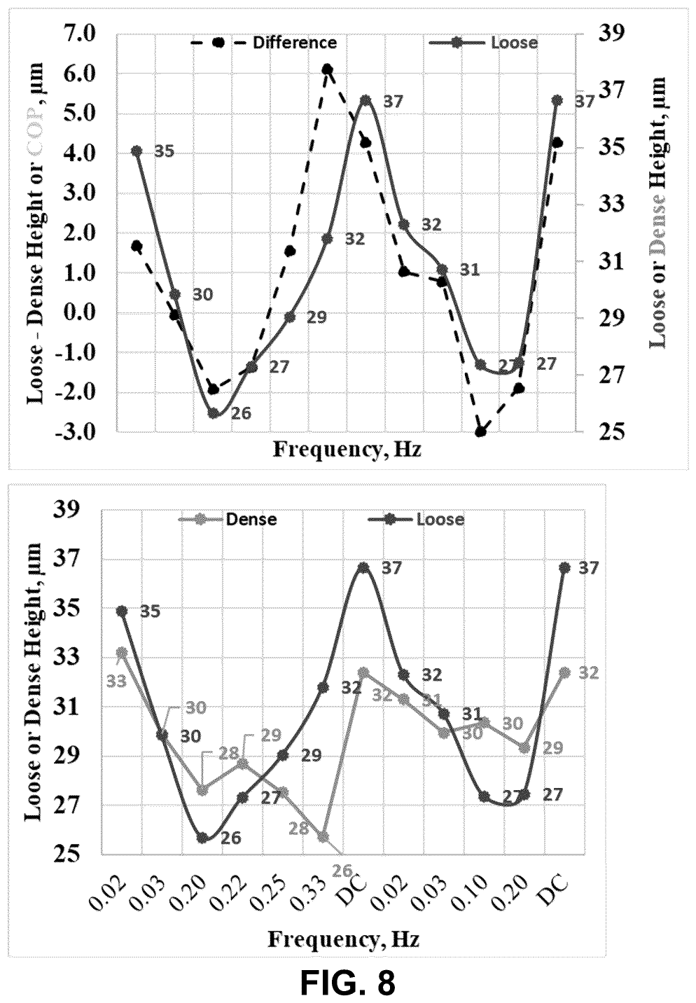

FIGS. 6-8 illustrate graphs of the resulting co-planarity using different current characteristics, according to some embodiments. These graphs represent experimental data or actual production data that have been observed and recorded from a large number of plating processes performed on different substrates. These data may represent trends that may be incorporated into the model through the training process. For example, as the training data sets described above are processed by the machine-learning algorithm, the internal parameters of the model are modified to move the output recipe values towards the optimal values suggested by the experimental data. These data are provided only by way of example and are not meant to be limiting, as they only show a limited set of experimental values on certain substrates with different processing recipe parameters.

The graphs illustrated in FIG. 6-8 illustrate the effect of adjusting the frequency between the forward and reverse currents. In this example, a current of 11 Amps/dm² (ASD) was applied at an 11:12 duty cycle. The experimental data illustrate how the co-planarity (COP)—or the difference between the loose or sparsely populated regions and the densely populated regions on the substrate—varies at different frequencies. For example, the COP is close to 0 for frequencies below about 0.1 Hz without a significant change in the morphology or quality of the metal pillars. However, higher frequencies that this duty cycle may be subject to potential defects in the surface quality of the pillars. Decreasing the forward current density may also allow for the decrease in the high de-plating current density to remove edge high bump defects.

Generally, the experimental data used to train the model has illustrated the following broadly applicable trends. While current density is directly proportional to the plating rate, the duty cycle is more specifically related to the COP result. Additionally, variations in frequency tend to be more specifically related to the quality of the pillars. Higher frequencies have generally been observed to decrease the size of holes or defects in the sidewall of the pillar. It should also be noted that there are dependencies between these different variables, so increasing the frequency may also affect the COP result to a lesser extent. Therefore, the optimal values for the frequency, duty cycle, and other curves are not always straightforward relationships that can be practically inferred by a human user simply analyzing the graph data. Instead, training the model to embody these relationships represented by the internal parameters of the model is a much more accurate and feasible method for finding an optical solution.

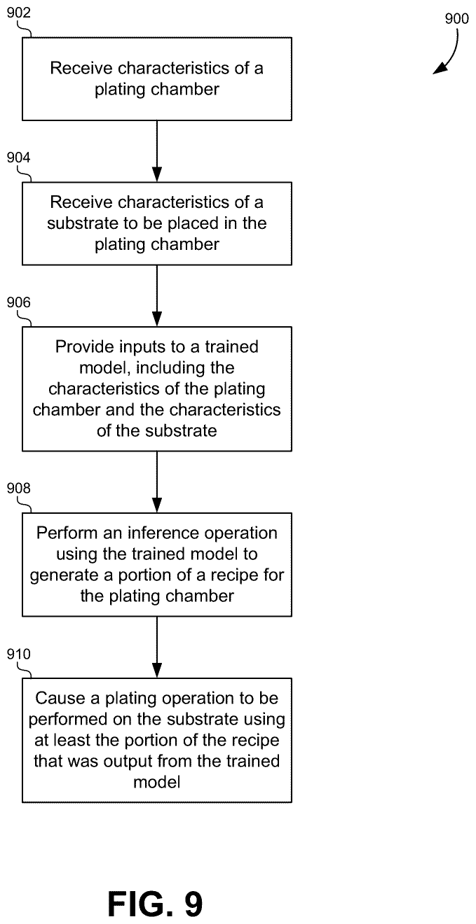

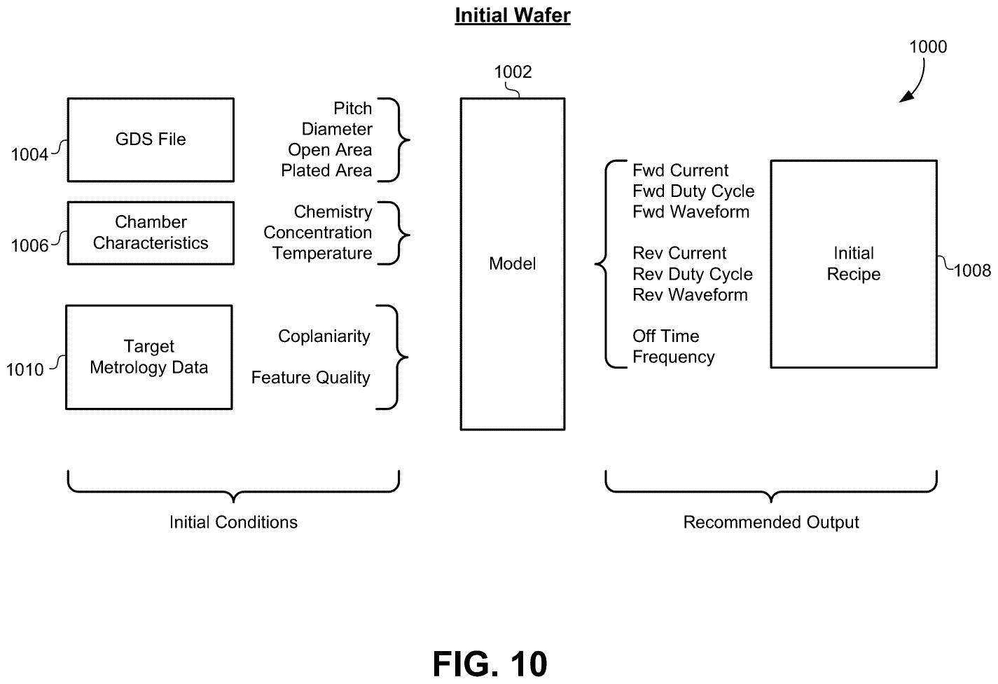

After the model has been trained using the training data described above, the model may be used for inference operations to determine optimal recipes for producing co-planar and low-defect plating processes. FIG. 9 illustrates a flowchart 900 of a method for plating semiconductor substrates, according to some embodiments. This process may be executed by a controller or other computer system in communication with the plating chamber. For example, the controller may include a computer system with one or more processors and one or more memory devices that store instructions to be executed by the processor(s). The memory device(s) may include one or more non-transitory, computer-readable media that store executable instructions. This process may be executed after the model has been trained using the process described above. Therefore, the model may be universally applicable to a large number of substrate types and/or different types of plating chambers. FIG. 10 illustrates a block diagram 1000 that illustrates the inference steps performed by the method of flowchart 900, according to some embodiments.

The method of flowchart 900 may be executed at the beginning of a batch process for plating a particular substrate type. For example, a new substrate design may be patterned and formed on a plurality of substrates (e.g., over 50 substrates). This substrate design need not have been part of any training data used to train the model. However, the model may be used as an instrument for providing an initial recipe to be used by the plating process. Since the general relationships between the recipe parameters and the co-planarity and quality of the plated pillars are encoded within the trained model, these general relationships may yield an initial recipe that is much closer to an optimal recipe than what have been used in the past.

The method may include receiving one or more characteristics of a plating chamber (902). The plating chamber may include an ECD plating chamber as described above in FIGS. 1-2, or any other type of plating chamber. For example, the plating chamber may include a plating liquid or electrolyte and may be configured to perform plating operations on semiconductor substrates. The characteristics of the plating chamber 1006 may include any of the characteristics described above and used during the training of the model. For example, the characteristics of the plating chamber 1006 may include a chemistry of the plating liquid, a concentration of plating liquid, environmental conditions such as temperature, humidity, pressure, etc., any gaseous species present in the plating chamber, and so forth. The characteristics of the plating chamber 1006 may be received as part of a set of known conditions for the plating process.

The method may also include receiving one or more characteristics of a substrate to be placed in the plating chamber (904). The characteristics of the substrate 1004 used when training the model may also be used here. For example, the characteristics of the substrate 1004 may include characteristics of the features or holes where pillars will be formed on the exposed areas of the substrate. These characteristics may include a pitch of the features, a diameter of the features, an area of the overall substrate or die represented by the features, and so forth. These characteristics may also include other characteristics of the substrate such as dimensions or characterizations of areas that are masked over the substrate, and a relationship or ratio between the open and masked areas. The characteristics of the substrate 1004 may be extracted from a GDS file that defines many aspects of the substrate design. The method may extract the relevant characteristics of the substrate for the plating process from the GDS file and encode these values as inputs for the model 1002.

Some embodiments may optionally provide target metrology data 1010 as an input to the model 1002. During the training process, this input included the measured metrology data from the previous plating processes. During the inference step illustrated in FIG. 10, the target metrology data 1010 may include a threshold or target range for co-planarity or feature quality. For example, the co-planarity threshold may include a value such as ±1.0 μm, ±1.5 μm, ±2.0 μm, ±2.5 μm, and so forth. In another example, the feature quality may include a threshold, such as a number of defects per square area, a size of holes or bumps in the pillars, or a numerical classification or rating of the quality of the pillars. These values may be provided as inputs to the model 1002, or these values may be automatically encoded as inputs to the model 1002 without requiring input during each inference session.

The method may further include providing inputs to a trained model (906). The inputs may include the one or more characteristics of the plating chamber 1006 and the one or more characteristics of the substrate 1004. Some embodiments may optionally include the target metrology data 1010 as inputs to the trained model 1002.

The method may additionally include performing an inference operation using the trained model to generate an output (908). The output may include at least a portion of a recipe for the plating chamber. For example, the portion of the recipe may include characteristics of a forward plating current and/or characteristics of a reverse de-plating current. Each of these characteristics may be provided as separate output ports from the model 1002. As described above, the characteristics of the plating and de-plating currents may include values such as a current density, a current magnitude, the voltage, a duty cycle, a delay, a waveform type, an off-time, DC components that are layered with pulsed components of the waveform, a frequency between the forward and reverse currents, and/or any other characteristics of these applied currents. These current characteristics may be imported into the initial recipe 1008 used to process a first substrate in the batch of new substrates that have the new substrate design. Based on previous techniques, this method of arriving at an initial recipe is much more efficient and much closer to an optimal recipe than previous methods that, for example, used a standard starting recipe for each substrate design.

The method may also include causing a plating operation to be performed on the substrate using at least the portion of the recipe that was output from the trained model (910). The recipe may cause a current to be applied to the plating liquid in the plating chamber to deposit a metal on exposed portions of the substrate as part of the plating process. As described above, the current may include alternating cycles of the forward plating current and the reverse de-plating current. During each cycle, the forward plating current may plate metal material in each of the features that expose the substrate through the mask. Since the forward plating current may unevenly plate the material, the reverse de-plating current may remove excess material from the pillars until co-planarity is achieved.

It should be appreciated that the specific steps illustrated in FIG. 9 provide particular methods of determining forward and reverse current values for a plating process according to various embodiments. Other sequences of steps may also be performed according to alternative embodiments. For example, alternative embodiments may perform the steps outlined above in a different order. Moreover, the individual steps illustrated in FIG. 9 may include multiple sub-steps that may be performed in various sequences as appropriate to the individual step. Furthermore, additional steps may be added or removed depending on the particular applications. Many variations, modifications, and alternatives also fall within the scope of this disclosure.

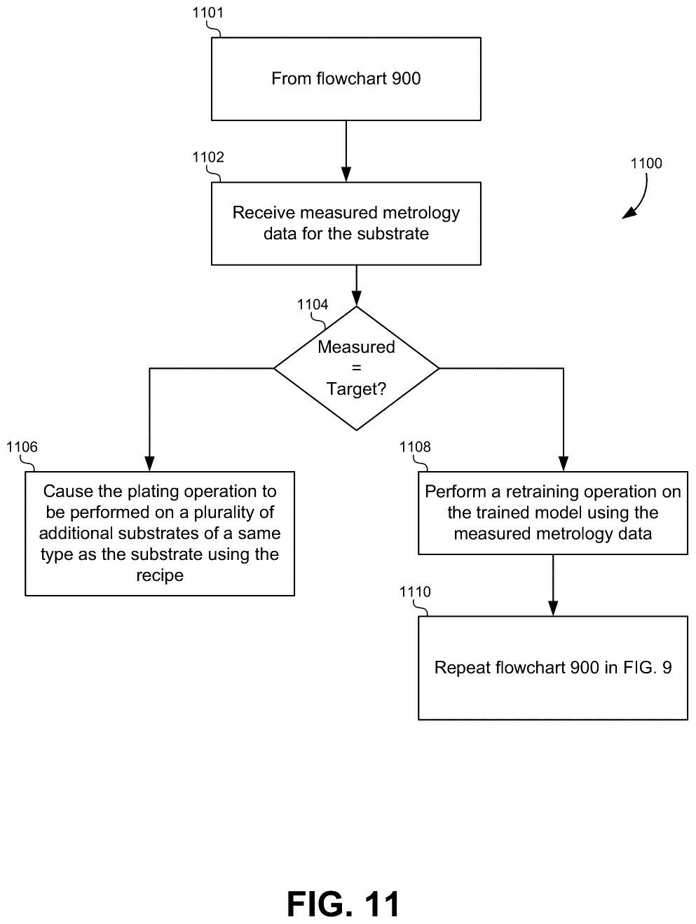

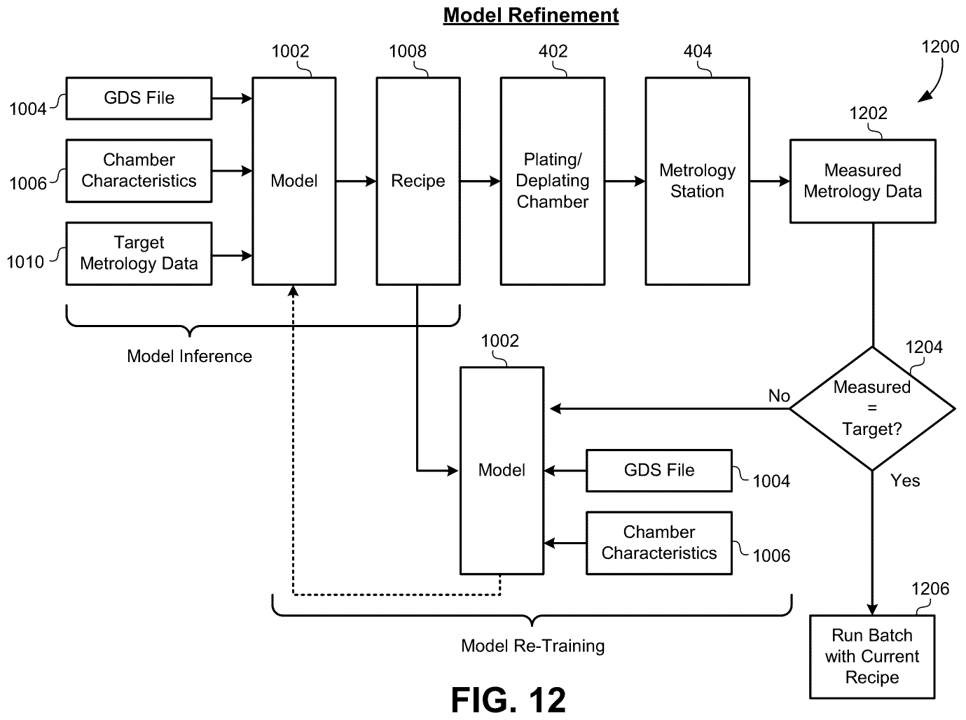

FIG. 11 illustrates a flowchart 1100 of a method for refining the trained model for a specific substrate type, according to some embodiments. FIG. 12 illustrates a block diagram of the operations performed by the method of flowchart 1100, according to some embodiments. This method may be executed after the method in flowchart 900 has been used to determine an initial recipe for the plating process, and after the resulting plating process has been executed on a substrate. Specifically, the method may begin after the method of flowchart 900 is completed (1101). For example, the recipe 1008 may be provided to the plating chamber 402 to plate the substrate, and the substrate may then be delivered to the metrology station 404.

The method may include receiving measured metrology data 1202 for the substrate (1102). The measured metrology data 1202 may be received from the metrology station 404 that measures various characteristics of the substrate. As described above, the measured metrology data may include characterizations of the co-planarity of the plated pillars on the substrate, along with a characterization of the quality of those pillars.

The method may further include determining whether the measured metrology data 1202 matches the target metrology data 1010 for the substrate (1204). For example, if the target metrology data 1010 includes acceptable thresholds or ranges for co-planarity or pillar quality, the corresponding values in the measured metrology data 1202 may be compared to these thresholds or ranges. Since the initial recipe generated by the model 1002 was based on training data not specific to this substrate in particular, the initial recipe may result in the actual metrology data not matching the target metrology data 1010 provided to the model 1002.

If it is determined that the measured metrology data 1202 does not sufficiently match the target metrology data 1010, then the method may additionally include performing a retraining operation on the trained model 1002 using the recipe 1008, the measured metrology data 1202, the characteristics of the plating chamber 1006, and/or the characteristics of the substrate 1004 (1108). This retraining operation may refine the model 1002 to be more specific to this particular substrate design. Therefore, some embodiments may more heavily weight the training data provided from the initial recipe when retraining the model 1002. For example, adjusting the internal weights or parameters of the trained model 1002 using these inputs may be more heavily weighted than the individual training data sets previously used on the model 1002 in FIG. 5. This retraining operation may use the actual measured metrology data 1202 from this substrate along with the recipe 1108 used to generate the measured metrology data as a training pair.

After the model 1002 has been retrained, the method described above in flowchart 900 may be repeated using the retrained model 1002. After the retraining procedure, the model 1002 may be more specifically tailored for this substrate design being processed in this particular processing chamber. Determining a new recipe from the retrained model may result in a substrate where the measured metrology data 1202 is much closer to the target metrology data 1010. Specifically, the same inputs may be provided to the retrained model after the retraining operation has been performed. The retrained model 1002 may then generate a new or next recipe, and the controller may cause the plating operation to be performed on a next substrate in the batch of substrates. The next substrate may then be analyzed by the metrology station, and the new metrology data may then be compared to the target metrology data to determine if further iterations of the retraining procedure for the model 1002 are needed. For example, the method may repeatedly perform iterative retraining operations until the measured metrology data matches the target metrology data.

Each retraining procedure will further cause the outputs of the model 1002 to converge towards the optimal values for the specific substrate. In practice, only a very small number of iterations to retrain the model 1002 are needed. For example, the model 1002 may converge to an optimal recipe that produces the target metrology data 1010 within two, three, or four iterations. This may be compared favorably to the much larger number of iterations previously required to optimize the recipe. This improvement may be attributed at least in part to the initial recipe generated by the universal model, and the refinement and retraining process to converge the universal model into a substrate-specific model.

When the measured metrology data 1202 matches the target metrology data 1010 after any of the executions of the plating process (1104), the process may cause the plating operation to be performed on a plurality of additional substrates in the batch that have the same type as the substrate using the most recent recipe generated by the model 1202. Essentially, when an optimal recipe is found, no further retraining of the model 1002 is needed, and the recipe generated by the model can be used on the batch of substrates.

When a new batch of substrates is received, the same process may be executed using the universal model. In some embodiments, the data from the retraining operations from the previous substrate may be used as training data for the universal model. In this case, the new training data may be weighted similarly to the previous training data rather than more heavily weighted for the specific substrate.

It should be appreciated that the specific steps illustrated in FIG. 11 provide particular methods of executing a plating process and retraining a model according to various embodiments. Other sequences of steps may also be performed according to alternative embodiments. For example, alternative embodiments may perform the steps outlined above in a different order. Moreover, the individual steps illustrated in FIG. 11 may include multiple sub-steps that may be performed in various sequences as appropriate to the individual step. Furthermore, additional steps may be added or removed depending on the particular applications. Many variations, modifications, and alternatives also fall within the scope of this disclosure.

Each of the methods described herein may be implemented by a computer system.

Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

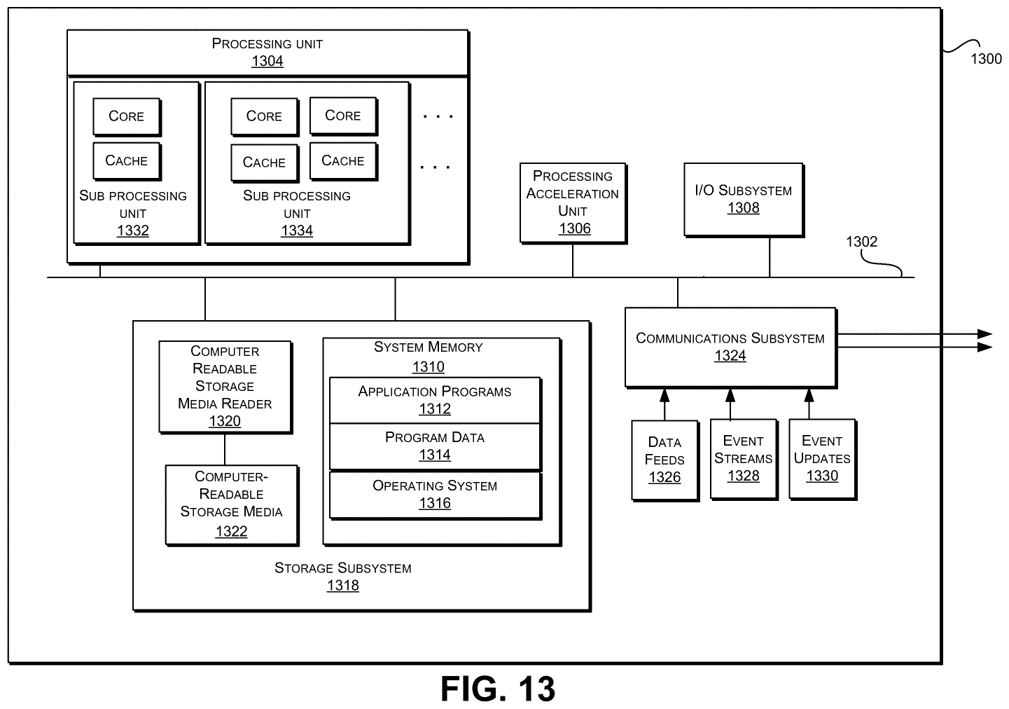

FIG. 13 illustrates an exemplary computer system 1300, in which various embodiments may be implemented. The system 1300 may be used to implement any of the computer systems described above. As shown in the figure, computer system 1300 includes a processing unit 1304 that communicates with a number of peripheral subsystems via a bus subsystem 1302. These peripheral subsystems may include a processing acceleration unit 1306, an I/O subsystem 1308, a storage subsystem 1318 and a communications subsystem 1324. Storage subsystem 1318 includes non-transitory, tangible, computer-readable storage media 1322 and a system memory 1310. The non-transitory computer-readable medium may store instructions that cause one or more processors to execute operations as described throughout this disclosure.

Bus subsystem 1302 provides a mechanism for letting the various components and subsystems of computer system 1300 communicate with each other as intended. Although bus subsystem 1302 is shown schematically as a single bus, alternative embodiments of the bus subsystem may utilize multiple buses. Bus subsystem 1302 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1304, which can be implemented as one or more integrated circuits (e.g., a conventional microprocessor or microcontroller), controls the operation of computer system 1300. One or more processors may be included in processing unit 1304. These processors may include single core or multicore processors. In certain embodiments, processing unit 1304 may be implemented as one or more independent processing units 1332 and/or 1334 with single or multicore processors included in each processing unit. In other embodiments, processing unit 1304 may also be implemented as a quad-core processing unit formed by integrating two dual-core processors into a single chip.

In various embodiments, processing unit 1304 can execute a variety of programs in response to program code and can maintain multiple concurrently executing programs or processes. At any given time, some or all of the program code to be executed can be resident in processor(s) 1304 and/or in storage subsystem 1318. Through suitable programming, processor(s) 1304 can provide various functionalities described above. Computer system 1300 may additionally include a processing acceleration unit 1306, which can include a digital signal processor (DSP), a special-purpose processor, and/or the like.

I/O subsystem 1308 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices such as the Microsoft Kinect® motion sensor that enables users to control and interact with an input device, such as the Microsoft Xbox® 360 game controller, through a natural user interface using gestures and spoken commands. User interface input devices may also include eye gesture recognition devices such as the Google Glass® blink detector that detects eye activity (e.g., ‘blinking’ while taking pictures and/or making a menu selection) from users and transforms the eye gestures as input into an input device (e.g., Google Glass®). Additionally, user interface input devices may include voice recognition sensing devices that enable users to interact with voice recognition systems (e.g., Siri® navigator), through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1300 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1300 may comprise a storage subsystem 1318 that comprises software elements, shown as being currently located within a system memory 1310. System memory 1310 may store program instructions that are loadable and executable on processing unit 1304, as well as data generated during the execution of these programs.

Depending on the configuration and type of computer system 1300, system memory 1310 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1304. In some implementations, system memory 1310 may include multiple different types of memory, such as static random access memory (SRAM) or dynamic random access memory (DRAM). In some implementations, a basic input/output system (BIOS), containing the basic routines that help to transfer information between elements within computer system 1300, such as during start-up, may typically be stored in the ROM. By way of example, and not limitation, system memory 1310 also illustrates application programs 1312, which may include client applications, Web browsers, mid-tier applications, relational database management systems (RDBMS), etc., program data 1314, and an operating system 1316. By way of example, operating system 1316 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1318 may also provide a tangible computer-readable storage medium for storing the basic programming and data constructs that provide the functionality of some embodiments. Software (programs, code modules, instructions) that when executed by a processor provide the functionality described above may be stored in storage subsystem 1318. These software modules or instructions may be executed by processing unit 1304. Storage subsystem 1318 may also provide a repository for storing data used in accordance with some embodiments.

Storage subsystem 1300 may also include a computer-readable storage media reader 1320 that can further be connected to computer-readable storage media 1322. Together and, optionally, in combination with system memory 1310, computer-readable storage media 1322 may comprehensively represent remote, local, fixed, and/or removable storage devices plus storage media for temporarily and/or more permanently containing, storing, transmitting, and retrieving computer-readable information.

Computer-readable storage media 1322 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1300.

By way of example, computer-readable storage media 1322 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1322 may include, but is not limited to, Zip® drives, flash memory cards, universal serial bus (USB) flash drives, secure digital (SD) cards, DVD disks, digital video tape, and the like. Computer-readable storage media 1322 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1300.

Communications subsystem 1324 provides an interface to other computer systems and networks. Communications subsystem 1324 serves as an interface for receiving data from and transmitting data to other systems from computer system 1300. For example, communications subsystem 1324 may enable computer system 1300 to connect to one or more devices via the Internet. In some embodiments communications subsystem 1324 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1324 can provide wired network connectivity (e.g., Ethernet) in addition to or instead of a wireless interface.

In some embodiments, communications subsystem 1324 may also receive input communication in the form of structured and/or unstructured data feeds 1326, event streams 1328, event updates 1330, and the like on behalf of one or more users who may use computer system 1300.

By way of example, communications subsystem 1324 may be configured to receive data feeds 1326 in real-time from users of social networks and/or other communication services such as Twitter® feeds, Facebook® updates, web feeds such as Rich Site Summary (RSS) feeds, and/or real-time updates from one or more third party information sources.

Additionally, communications subsystem 1324 may also be configured to receive data in the form of continuous data streams, which may include event streams 1328 of real-time events and/or event updates 1330, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1324 may also be configured to output the structured and/or unstructured data feeds 1326, event streams 1328, event updates 1330, and the like to one or more databases that may be in communication with one or more streaming data source computers coupled to computer system 1300.

Computer system 1300 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 1300 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A method of plating semiconductor substrates, the method comprising:
receiving one or more characteristics of a plating chamber comprising a plating liquid and configured to perform plating operations on semiconductor substrates;
receiving one or more characteristics of a substrate to be placed in the plating chamber;
providing inputs to a trained model, wherein the inputs comprise the one or more characteristics of the plating chamber and the one or more characteristics of the substrate;
performing an inference operation using the trained model to generate an output comprising at least a portion of a recipe for the plating chamber, wherein the portion of the recipe comprises characteristics of a forward plating current and characteristics of a reverse de-plating current;
causing a plating operation to be performed on the substrate using at least the portion of the recipe that was output from the trained model, wherein the recipe causes a current to be applied to the plating liquid in the plating chamber to deposit a metal on exposed portions of the substrate, wherein the current comprises alternating cycles of:
the forward plating current; and
the reverse de-plating current.

2. The method of claim 1, further comprising:
causing the substrate to be transferred from the plating chamber to a metrology station; and
causing metrology station to analyze the substrate and obtain metrology data for the substrate.

3. The method of claim 2, wherein the metrology data comprises a measure of a within-wafer or within-die co-planarity of metal pillars that fill the exposed portions of the substrate during the plating operation.

4 The method of claim 2, wherein the metrology data comprises a characterization of a quality of metal pillars that fill the exposed portions of the substrate during the plating operation.

5. The method of claim 1, further comprising:
receiving measured metrology data for the substrate;
determining that the measured metrology data matches a target metrology data for the substrate; and
in response to determining that the measured metrology data matches the target metrology data, causing the plating operation to be performed on a plurality of additional substrates of a same type as the substrate using the recipe that was output from the trained model.

6. The method of claim 1, further comprising:
receiving measured metrology data for the substrate;
determining that the measured metrology data does not match a target metrology data for the substrate; and
in response to determining that the measured metrology data matches the target metrology data, performing a retraining operation on the trained model using the recipe, the measured metrology data, the one or more characteristics of the plating chamber, and the one or more characteristics of the substrate.

7. The method of claim 6, wherein the retraining operation comprises:
adjusting internal weights or parameters of the trained model using the one or more characteristics of the plating chamber, the one or more characteristics of the substrate, and the measured metrology data as inputs, and using the recipe as a labeled output.

8. The method of claim 6, further comprising repeatedly performing iterative operations until the measured metrology data matches the target metrology data, wherein the iterative operations comprise:
providing the inputs to the trained model after the retraining operation has been performed;
generating a next recipe using the trained model;
causing the plating operation to be performed on a next substrate using the next recipe;
receiving next measured metrology data for the next substrate after the plating operation is performed; and
determining whether the next measured metrology data matches the target metrology data.

9. The method of claim 1, wherein the inputs to the trained model further comprise target metrology data.

10. One or more non-transitory computer-readable media comprising instructions that, when executed by one or more processors, cause the one or more processors to perform operations comprising:
receiving one or more characteristics of a plating chamber comprising a plating liquid and configured to perform plating operations on semiconductor substrates;
receiving one or more characteristics of a substrate to be placed in the plating chamber;
providing inputs to a trained model, wherein the inputs comprise the one or more characteristics of the plating chamber and the one or more characteristics of the substrate;
performing an inference operation using the trained model to generate an output comprising at least a portion of a recipe for the plating chamber, wherein the portion of the recipe comprises characteristics of a forward plating current and characteristics of a reverse de-plating current;
causing a plating operation to be performed on the substrate using at least the portion of the recipe that was output from the trained model, wherein the recipe causes a current to be applied to the plating liquid in the plating chamber to deposit a metal on exposed portions of the substrate, wherein the current comprises alternating cycles of:
the forward plating current; and
the reverse de-plating current.

11. The one or more non-transitory computer-readable media of claim 10, wherein the one or more characteristics of the substrate are received as a GDS file for the substrate.

12. The one or more non-transitory computer-readable media of claim 10, wherein the one or more characteristics of the substrate comprises a characterization of an amount of masked area of the substrate relative to the exposed portions of the substrate.

13. The one or more non-transitory computer-readable media of claim 10, wherein the one or more characteristics of the substrate comprises a diameter or pitch of vias that form the exposed portions of the substrate.

14. The one or more non-transitory computer-readable media of claim 10, wherein the one or more characteristics of the plating chamber comprise a temperature or pressure of the plating chamber.

15. A controller for a plating chamber, the controller comprising:
one or more processors; and
one or more memory devices storing instructions that, when executed by the one or more processors, cause the one or more processors to perform operations comprising:
receiving one or more characteristics of a plating chamber comprising a plating liquid and configured to perform plating operations on semiconductor substrates;
receiving one or more characteristics of a substrate to be placed in the plating chamber;
providing inputs to a trained model, wherein the inputs comprise the one or more characteristics of the plating chamber and the one or more characteristics of the substrate;
performing an inference operation using the trained model to generate an output comprising at least a portion of a recipe for the plating chamber, wherein the portion of the recipe comprises characteristics of a forward plating current and characteristics of a reverse de-plating current;
causing a plating operation to be performed on the substrate using at least the portion of the recipe that was output from the trained model, wherein the recipe causes a current to be applied to the plating liquid in the plating chamber to deposit a metal on exposed portions of the substrate, wherein the current comprises alternating cycles of:
the forward plating current; and
the reverse de-plating current.

16. The controller of claim 15, wherein the substrate comprises a photoresist or mask layer that defines a pattern on the substrate, and the pattern comprises exposed portions of the substrate adjacent to an open area, wherein a current density during a plating process is more concentrated at the exposed portions of the substrate adjacent to the open area compared to exposed portions of the substrate that are not adjacent to the open area.

17. The controller of claim 15, wherein, during the forward plating current, the metal is deposited unevenly on the exposed portions of the substrate.

18. The controller of claim 17, wherein, during the reverse deplating current, the metal is removed such that the metal becomes evenly distributed on the exposed portions of the substrate.

19. The controller of claim 15, wherein the forward plating current and the reverse deplating current are both applied in alternating cycles in the plating chamber when the substrate is in the plating liquid without using separate chambers or plating liquids to apply the forward plating current and the reverse deplating current.

20. The controller of claim 15, wherein the exposed portions of the substrate comprise a plurality of thru-silicon vias (TSVs), where a difference between a maximum height of the TSVs and a minimum height of the TSVs is greater than a threshold distance.
